(19) United States
(12) Patent Application Publication
(10) Pub. No.: US 2009/0116260 A1
(43) Pub. Date: May 7, 2009

(54) LIGHTING DEVICE FOR VIDEOENDOSCOPE

(75) Inventor: Jean Rovegno, La Ciotat (FR)

Correspondence Address: SEED INTELLECTUAL PROPERTY LAW GROUP PLLC, 701 FIFTH AVE, SUITE 5400, SEATTLE, WA, 98104, US

(73) Assignee: TOKENDO, La Ciotat (FR)

(21) Appl. No.: 12/261,848

(22) Filed: Oct. 30, 2008

(30) Foreign Application Priority Data
Oct. 31, 2007 (FR) 0707645

(51) Int. Cl. H01L 33/00

(52) U.S. Cl. 362/555

(57) ABSTRACT

A lighting device for videoendoscopic probe, comprising a light generator comprising a case wherein are mounted a light-emitting diode, a lighting endpiece attached to the end of the bundle of lighting fibers configured to adapt the surface of the proximal end of the bundle of lighting fibers to the light-emitting surface of the diode, and a connection part configured to be fixed on a handle of videoendoscopic probe, and to couple with the case, the case and the connection part being configured to maintain the lighting endpiece on the light-emitting surface.

### BACKGROUND

1. Technical Field

The present invention relates to a lighting device allowing the proximal end of a bundle of lighting optical fibers to be illuminated. The present invention applies particularly, but not exclusively, to the field of industrial endoscopy.

2. Description of the Related Art

The terms “endoscope” or “fiberscope” refer to a rigid or flexible probe, intended for being introduced into a dark cavity and allowing the user thereof to observe through an eyepiece the image of a target located in the cavity. Such a probe integrates to that end a device for lighting the target and an optical device supplying to the user an image of the target. The optical device comprises a distal objective, a device for carrying images of rigid nature constituted by a series of lenses, or of flexible nature constituted by a bundle of arranged optical fibers, and a proximal eyepiece. The lighting device usually comprises a bundle of lighting fibers having a distal end, properly directed near the distal objective, that illuminates the target when the proximal end thereof is connected to a white light generator.

The term “videoendoscope” refers to an endoscopy system allowing the user thereof to observe on a video screen the image of a target located in a dark cavity. A videoendoscope comprises a videoendoscopic probe, devices for utilizing annexes and means for arranging and carrying.

A videoendoscopic probe comprises the following elements:

a distal endpiece housing an optoelectronic device of small dimensions comprising in particular an image sensor, such as for example an interline transfer tree-CCD, comprising a photosensitive surface onto which an image issued by an objective associated to the image sensor is formed,

an inspection tube, generally of flexible nature, having a distal that end is attached to the distal endpiece,

a control handle attached to the proximal end of the inspection tube,

a flexible umbilical tube comprising a distal end attached to the control handle and a proximal end equipped with a multiple connector allowing the probe to be connected to attached managing devices which are functionally associated thereto,

a lighting device usually comprising a bundle of lighting fibers successively housed in the umbilical tube, the control handle, and the inspection tube, the bundle of fibers comprising a distal end integrated into the distal endpiece, to illuminate the target when the proximal end thereof, integrated into the multiple connector of the probe, is connected to a light generator,

a video processor for example integrated into the control handle, linked to the distal image sensor by a multicore electric cable housed in the inspection tube, the video processor being configured to transform into a useful video signal the electrical signal issued by the image sensor, the video processor being in addition synchronized by a setting originally performed as a function of the length and features of the multicore cable,

a flat screen for example embedded into the control handle and allowing the useful video signal issued by the video processor to be viewed,

a panel of control keys also embedded for example on the control handle, and allowing in particular the user to adjust the value of the operating parameters of the video processor. The videoendoscopic probes may in addition have the following elements:

an articulated distal tip deflection allowing the angle of the distal endpiece of the probe to be modified, the tip deflection comprising mechanical or electromechanical means configured to control the tip deflection, which are for example integrated into the control handle of the probe,

interchangeable optical heads which can be locked on the distal endpiece of the probe and allowing all or part of the following optical parameters to be modified: field covered by the probe, focusing distance, depth of field and look direction.

The attached managing devices susceptible of being functionally associated to the videoendoscopic probe are the following:

a power supply which may consist of a battery or a case which may be connected to a source of alternating or direct voltage,

a light generator traditionally organized around a halogen or xenon bulb,

a video monitor,

a video image recorder/reader,

a digital device for freezing, saving and processing images, this device may be a simple portable computer equipped with a video input, or a dedicated system managed by the control panel embedded into the control handle of the videoendoscopic probe,

a metrology device allowing the user to measure in situ, on a previously frozen video image of a target being inspected, the real dimensions of some elements of the target, the metrology device generally comprising a specific optical means integrated into a removable distal head and a specific pointing and calculation program managed by the digital image processing device.

The significant improvements lately noticed in videoendoscopy result from the miniaturization of some components. This miniaturization made it possible to integrate into the video processor of the videoendoscopic probe one or more dedicated digital operators, configured to perform in real time functions such as image freezing, zooming, image inversion, low speed video shutter, images saving, implementing a “PC compatible” support and format. This miniaturization has also made it possible to use as light source of the lighting device of the videoendoscopic probe one or more light-emitting diodes (LED).

Historically, the first lighting devices used in rigid endoscopy (see in particular U.S. Pat. No. 2,779,327, U.S. Pat. No. 3,096,756) comprised as light source a filament lamp integrated into the distal end of a lateral vision endoscope. This lamp was associated to a mirror intended for laterally deflecting the luminous flux thereof so that the illumination field covers the optical field of the endoscope. Such devices keep being used nowadays with lamps of halogen type of small dimensions.

The popularization of flexible lighting fibers has then caused the generalization, in rigid endoscopy as well as fiberscopy, and then videoendoscopy, of lighting devices comprising a bundle of lighting fibers housed in the endoscopic probe and linking the distal endpiece of the probe to a light generator.

A variation of this solution, described in particular in the patent FR 2 785 132, consists in directly housing in the handle of the endoscopic probe a light generator comprising a lamp of average power.

Today, it may be noted that the implementation of light-emitting diodes, instead of traditional lamps of halogen or xenon type, constitutes a real improvement in terms of portability and energy consumption.

The first lighting diodes available were miniaturized components having a power of 5 to 100 mW. These diodes were mainly used to enlighten sensitive control keys or perform a global backlighting of a keyboard. Then, diodes of a power of 300 to 800 mW in continuous rating appeared, which were susceptible of being powered in pulsed mode in flash units of digital cameras. Eventually, lighting diodes of general use were recently implemented. These diodes of a power comprised between 1 and 5 W have an emitting surface which may reach 1 mm², and are originally associated to a plastic optical lens to diffuse the emitted light in a wide solid angle.

The apparition of various models of light-emitting diodes mentioned hereinbefore allowed various types of architectures to be considered.

In a first type of architecture, the bundle of lighting fibers has been suppressed by directly integrating one or more miniaturized light-emitting diodes in the distal end of the endoscopic probe. The U.S. Pat. No. 5,908,294 thus describes a rigid lateral vision videoendoscopic probe which distal end houses two LEDs which illumination field covers the optical field of the probe. The U.S. Pat. No. 5,264,925, U.S. Pat. No. 6,033,087, U.S. Pat. No. 6,449,006, US 2003/0 035 048 and US 2004/0 064 018 describe axial vision videoendoscopic probes which lighting device comprises several light-emitting diodes concentrically arranged around the objective of the probe. In the patent applications WO 2005/032 356, WO 2006/001 377 and WO 2006/046 559, it has also been considered to house in a removable distal head an optical device and a lighting device consisting of one or more miniaturized lighting diodes.

In a second type of architecture, the lighting device comprises several LEDs arranged on a concave support which may be associated to an optical device to focus the luminous flux emitted by the LEDs onto the proximal end of a bundle of lighting fibers. Such lighting devices are described in particular in the documents U.S. Pat. No. 6,260,994, U.S. Pat. No. 6,438,302, US 2003/0 156 430, US 2003/0 235 800 and U.S. Pat. No. 6,932,599. In the second type of architecture, several diodes arranged on a plane support may be associated to a focus optical device (JP 2006/122251), or a concave mirror associated to an optical lens (U.S. Pat. No. 6,318,887).

In a third type of architecture, one or more light-emitting diodes are integrated into the control handle of the endoscopic probe and optically coupled to the proximal end of a bundle of lighting fibers housed in the probe. In a first solution described in the U.S. Pat. No. 6,730,019 several diodes are longitudinally integrated into the control handle. Each of these diodes is associated to a focus lens and a semi-reflective prism, arranged so as to channel the luminous flux emitted by the diode on the proximal end of the bundle of lighting fibers housed in the probe. A second solution described in the document GB 2 357 856 provides to integrate a crown of light-emitting diodes into the control handle. The diodes are directly associated to the proximal end of the bundle of lighting fibers, arranged in crown shape. A third solution provides to integrate into the control handle of the endoscopic probe one light-emitting diode of a sufficient power. The diode is then coupled to the proximal end of the bundle of lighting fibers housed in the probe either directly (documents U.S. Pat. No. 7,198,397 and U.S. Pat. No. 7,229,201), or through an optical device (U.S. Pat. No. 7,063,663).

Currently, a complete range of videoendoscopic probes have diameters comprised between 4 mm to 8 mm. It is therefore desirable to design a light-emitting diode lighting device adapted to such a range.

Given the geometric constraints imposed by the diameter of the probes, the lighting device may only be integrated into the distal end of the videoendoscopic probe, into a removable distal head, or in the control handle of the probe.

If the lighting device is integrated into the distal end of the probe or in a removable distal head, the best light efficacy is obtained since it is not necessary to associate the LEDs which directly illuminate the target to a distal optical device or an optical fiber coupling device. However, this solution proves to be delicate to implement in probes of small diameters because the low internal volume of the distal end of the probe does not allow LEDs emitting a sufficient global lighting power to be integrated.

It has also been considered to arrange one or more LEDs near the distal CCD sensor and to use a low speed electronic shutter device increasing the duration of the integration period of the sensor, in order to compensate the low lighting power. However, this solution may cause an increase in temperature, which is detrimental for the good operation of the CCD sensor.

If the lighting device is integrated into the control handle of the endoscopic probe, the section of the bundle of lighting fibers transmitting the luminous flux emitted from the handle to the distal end of the videoendoscopic probe has a surface of around 5 mm² for probes of 8 mm diameter. This surface is reduced to 2 mm² for probes of 6 mm diameter and to 1 mm² for probes of 4 mm diameter. By experience, the electric power of a light-emitting diode having a sufficient efficacy and susceptible of being integrated into a lighting device common to the probes of the tree diameters mentioned hereinbefore must be at least equal to 10 W.

The lighting device may comprise one LED which light emitting surface is coupled to the proximal end of the bundle of lighting fibers. It is important in this case that the dimensions and the power of the luminous flux emitted, either directly by the light-emitting surface of the diode, or by a coupling optical device associated to the diode, is adapted to the section surface of the bundle of fibers to which it is coupled.

The principle of directly coupling a bundle of lighting fibers to a light-emitting diode was described as soon as 1980 in the U.S. Pat. No. 4,212,021. The implementation of such a lighting device in an endoscopic probe was then considered in the U.S. Pat. No. 6,921,920, U.S. Pat. No. 7,198,397 and U.S. Pat. No. 7,229,201. In the two last patents, the lighting diode used is encapsulated into a plastic dome containing an optical silicon gel, serving as optical lens. The implementation of such a component implies, as it was specified in these patents, previously removing the plastic gel and optical gel so as to allow the emitting surface of the diode to be directly coupled to the proximal end of the bundle of lighting fibers. Be that as it may, the features of the LED implemented in these two patents (light-emitting surface of square shape of around 1 mm², electric power of around 4 W) do not authorize it to be used in a complete range of videoendoscopic probes having diameters comprised between 4 mm and 8 mm.

Is has also been considered in the documents US 2002/0 076 174, US 2003/0 147 254, U.S. Pat. No. 6,921,920 and US 2006/0 171 693 to implement a coupling optical device allowing the emitting surface of a light-emitting diode to be coupled to a bundle of optical fibers which section has a surface greater than the light-emitting surface of the diode. Now the light efficacy of such a coupling optical device proves to be insufficient in practice and unacceptable in endoscopy, in particular with a diode of insufficient power.

In addition, the integration into the control handle of a videoendoscopic probe of a light-emitting diode of a sufficient power to perform the illumination of a bundle of lighting fibers of big section arises cooling problems delicate to resolve. For example, in FIG. 5 of the U.S. Pat. No. 7,198,397, the control handle of the endoscopic probe is metallic and comprises an internal metallic plate supporting a light-emitting diode. The whole handle thus acts as a radiator allowing the heat given off by the diode to be evacuated toward the exterior. Such a solution has a limited interest in that it cannot be implemented in a control handle made in a not thermally conductive material, such as injected plastic. This solution has in addition proven not to allow a light-emitting diode of a power greater than 5 Watts to be efficiently cooled down. The addition on the support of the diode of a Peltier effect cooling cell does not make it possible to solve this problem in that it is necessary to evacuate the calories given off by the cell toward the exterior. The addition on one of the external faces of the control handle of a natural ventilation external radiator of the type of those described in the document US 2006/0 171 693 allows, by means of a substantial increase in the dimensions of the handle, LEDs of a power of around 10 Watts to be implemented.

### BRIEF SUMMARY

Thus, in an embodiment, a lighting device for videoendoscopic probe equipped with a bundle of lighting fibers is provided, the lighting device comprising at least one light-emitting diode. According to one embodiment, the lighting device comprises: a light generator comprising a case wherein are mounted the diode, a lighting endpiece attached to a proximal end of the bundle of lighting fibers configured to adapt the surface of the proximal end of the bundle of lighting fibers to the light-emitting surface of the diode, and a connection part configured to be fixed to a handle of videoendoscopic probe, and to couple with the case, the case and the connection part being configured to maintain the lighting endpiece on the light-emitting surface.

According to one embodiment, the case is thermally linked to the diode and is configured to evacuate the heat given off by the diode.

According to one embodiment, the lighting device comprises a forced cooling device installed in the case and thermally linked to the diode.

According to one embodiment, the case comprises blades forming a radiator, thermally linked to the diode.

According to one embodiment, the case is configured so as to be removably fixed to the connection part.

According to one embodiment, the lighting device comprises a ring encircling the case and fixed to the case so as to be able to freely turn around its axis, the connection part comprising an external thread configured to cooperate with an internal thread provided in the ring and thus performing fixing the case to the connection part.

According to one embodiment, the light-emitting surface of the light-emitting diode has a surface greater than 3 mm², and consumes an electrical power greater than 10 Watts.

According to one embodiment, the light-emitting diode comprises a light-emitting surface of around 4 mm², and consumes an electrical power greater than 15 Watts.

According to one embodiment, the lighting endpiece is configured to couple a bundle of lighting fibers having a proximal surface of around 5 mm², to the emitting surface of around 4 mm².

According to one embodiment, the emitting surface of the diode is of substantially square shape, the proximal face of the bundle of fibers being conformed in the lighting endpiece in order to have a substantially square shape.

According to one embodiment, the lighting endpiece comprises a lateral lug cooperating with a housing provided in the connection part to maintain the proximal end of the bundle of lighting fibers substantially in contact with the emitting surface and in an angular configuration able to cover the whole emitting surface.

According to one embodiment, the lighting endpiece is configured to couple a bundle of lighting fibers having a proximal surface of around 2 mm² to the emitting surface of around 4 mm².

According to one embodiment, the lighting endpiece is configured to couple a bundle of lighting fibers having a proximal surface of around 1 mm² to the emitting surface of around 4 mm².

According to one embodiment, the lighting endpiece comprises an optical component having a proximal face configured to cover the emitting surface, and a distal face substantially identical to the proximal face of the bundle of lighting fibers, the surface of the proximal face being greater than that of the distal face.

According to one embodiment, the lighting endpiece comprises longitudinal cylindrical housings configured to receive the proximal ends of sub-bundles obtained by the division of the bundle of lighting fibers, the cylindrical housings being arranged to center the proximal ends of the sub-bundles on light-emitting areas of the light-emitting diode.

According to one embodiment, the lighting endpiece comprises a lateral lug cooperating with a housing provided in the connection part to maintain each proximal end of the sub-bundles centered on a respective light-emitting area and substantially in contact therewith.

According to one embodiment, the connection part comprises an electrical connection base configured to couple with an electrical connection base attached to the case when the case and the connection part are coupled.

According to one embodiment, the lighting endpiece is axially maintained in the connection part and the case, the electrical connection bases being fixed off-center in the connection part and the case, thus defining an angular configuration of fixation of the case on the connection part.

In an embodiment, a videoendoscopic probe comprising a bundle of lighting fibers and a control handle comprising a case are provided. According to one embodiment, the videoendoscopic probe comprises a lighting device as defined hereinbefore, the lighting endpiece being coupled to the proximal end of the bundle of lighting fibers, and the connection part being fixed to the case of the control handle.

According to one embodiment, the connection part comprises an annular groove provided to receive the edges of an annular orifice formed by two half-shells forming at least partially the case of the control handle.

According to one embodiment, the half-shells are made in a plastic compound.

### BRIEF DESCRIPTION OF THE SEVERAL VIEWS OF THE DRAWINGS

Some embodiments of the invention will be described hereinafter in relation with, but not limited to the appended figures wherein:

FIG. 1 shows in perspective a lighting device according to one embodiment,

FIG. 2 is an exploded view in perspective of the lighting device,

FIG. 3 is a front view of a board supporting a light-emitting diode of the lighting device,

FIG. 4 shows a light-emitting surface of the light-emitting diode,

FIGS. 5 and 5A show in perspective a mode for coupling a bundle of lighting fibers to the light-emitting surface, according to a first embodiment,

FIG. 6 shows the section of the bundle of lighting fibers of FIGS. 5 and 5A, superimposed to the light-emitting surface,

FIGS. 7 and 7A show in perspective a mode for coupling a bundle of lighting fibers to the light-emitting surface, according to a second embodiment,

FIG. 8 shows the section of the bundle of lighting fibers of FIGS. 7 and 7A, superimposed to the light-emitting surface,

FIGS. 9 and 9A show in perspective a mode for coupling a bundle of lighting fibers to the light-emitting surface, according to a third embodiment,

FIG. 10 shows the section of the bundle of lighting fibers of FIGS. 9 and 9A, superimposed to the light-emitting surface,

FIGS. 11 and 12 are perspective views of control handles of videoendoscopic probes associated to the lighting device.

### DETAILED DESCRIPTION

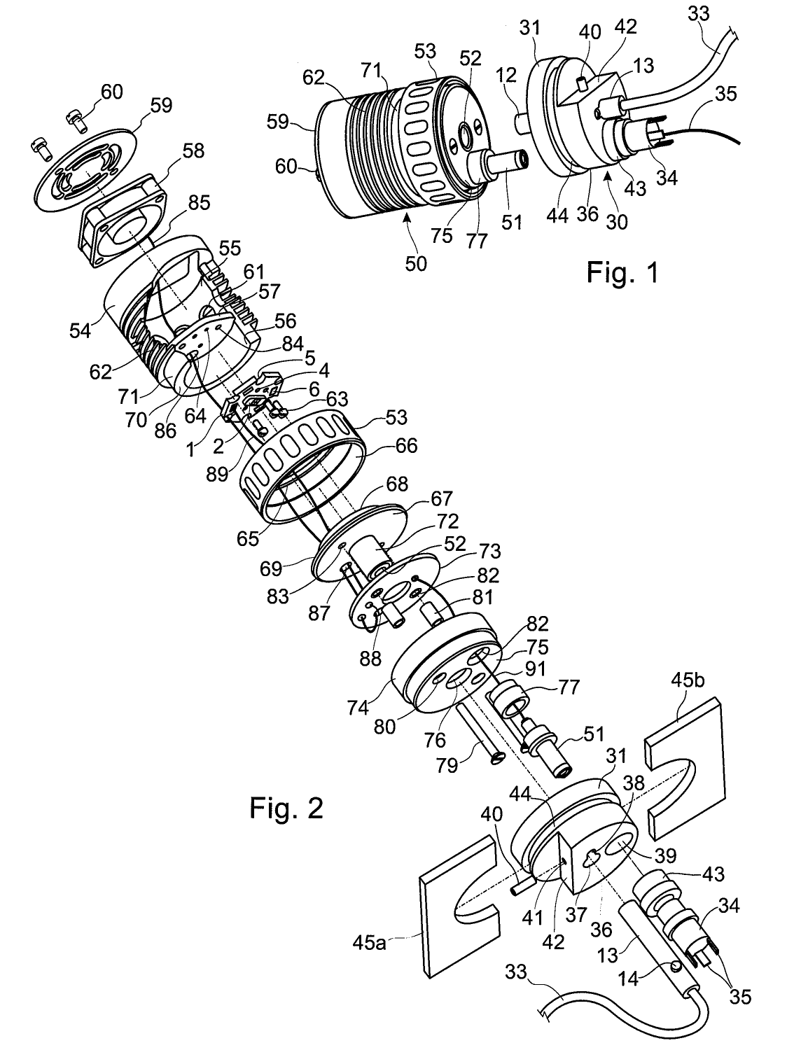

FIGS. 1 and 2 show a lighting device for videoendoscopic probe according to one embodiment. The lighting device comprises an external light generator 50, and a connection part 30 adapted for being fixed to a control handle of videoendoscopic probe. The light generator 50 is adapted for being removably fixed to the connection part 30.

The light generator 50 comprises a light-emitting diode 2 consuming an electrical power greater than 10 Watts, for example greater than 15 Watts, and having a light-emitting surface greater than 3 mm², for example around 4 mm². The generator 50 also comprises a forced cooling device 58 adapted for evacuating the heat given off by the diode. The forced cooling device comprises a ventilator and cooling blades in limited number and dimensions, formed on the generator 50. The light generator has a compact shape, for example substantially cylindrical, of 35 mm diameter and 35 mm length.

The connection part 30 supports a female electrical connection base 34 and a lighting endpiece 13 of substantially cylindrical shape. The base 34 is powered inside the control handle by an electric cable 35. The lighting endpiece 13 is permanently attached to the proximal end of a bundle of lighting fibers 33 of the videoendoscopic probe.

To be able to be associated with a range of videoendoscopic probes having useful diameters comprised between 4 mm and 8 mm, the endpiece 13 has an internal optical structure adapted to the diameter of the section of the bundle of lighting fibers. The lighting endpiece 13 has a proximal part 12 arranged to be projecting on the external proximal face of the connection part 30, so as to be connected to the light generator 50.

The substantially circular proximal face of the light generator 50 has an off-centered male electric connection base 51 intended for being plugged into the proximal part of the female electric connection base 34 of the connection part 30. The proximal face of the generator 50 also comprises an axial cylindrical orifice 52 intended for receiving the proximal part of the lighting endpiece 13 attached to the connection part 30.

The generator 50 may be removably fixed to the connection part, for example using a freely rotating ring 53 encircling the light generator 50 and having an internal thread compatible with an external thread 31 formed around the proximal part of the connection part 30. The combination of an axial “light” connection formed by the endpiece 13 and the orifice 52, and an off-centered electric connection formed by the bases 51 and 34, allows the light generator 50 to be locked in relation to the connection part 30 in an angular position determined by the angular position of the off-centered electric connection.

The connection part 30 comprises a core 36, metallic for example, which proximal part comprises a cylindrical cup encircled by the external thread 31. The core 36 comprises an axial cylindrical channel 37 and an off-centered cylindrical channel 39. The distal part of the axial channel 37 has a lateral recess 38. The core 36 also comprises a lateral flat section 42 machined on a distal part of the core, and a threaded radial through-channel 41 formed between the flat section 42 and the axial channel 37.

The lighting endpiece 13 attached to the bundle of lighting fibers 33 is introduced into the distal part of the axial channel 37 until a lateral pin 14 attached to the endpiece 13 finds its position in the housing formed by the lateral recess 38. A screw 40 introduced into the radial channel 41 made in the distal part of the core 36 allows the endpiece 13 to be fixedly maintained in position in the axial channel 37. It is to be noted that the mechanical coupling between the pin 14 and the recess 38 allows the endpiece 13 to be locked in relation to the connection part 30 in an angular position determined by the angular position of the recess 38. As the coupling between the connection part 30 and the generator 50 is also performed in a determined angular position, the endpiece 13 is also locked in a determined angular position in relation to the generator 50.

The electric connection base 34 is introduced and fixed into the off-centered axial channel 39 of the core, for example through a tubular part 43 in an electrically insulating material. To that end, the distal part of the off-centered cylindrical channel 39 is for example internally threaded. The tubular part 43 likewise comprises in proximal part for example an external threading allowing it to be screwed into the internally threaded distal part of the off-centered channel 39. The distal part of the insulating tubular part 43 also has an internal thread allowing the female electric connection base 34 to be screwed inside the part 43.

The external medial part of the metallic core 36 comprises a circular groove 44 with square profile allowing the core to be embedded into a joint plane between two half-shells 45a, 45b forming the case of the control handle of a videoendoscopic probe. In other words, the half-shells 45a, 45b form, when they are assembled, a circular orifice wherein the core is embedded, the edges of the circular orifice being fit in the annular groove 44. The half-shells 45a, 45b are for example made in injected plastic.

The light generator 50 comprises a case or core 54 of cylindrical shape partially shown in FIG. 2. The core 54 comprises a proximal axial orifice 55 and a distal axial orifice 56 separated from one another by a transversal partition 57. The core 54 is made in a thermally conductive material, for example in a metal. The core 54 comprises lateral orifices 61 formed in the central part of the core and therefore of the axial orifice 55 and external blades 62 machined around the central part of the core. A ventilator 58 is housed in the proximal part of the orifice 55 and permanently maintained therein using a pierced circular fixing plate 59 and for example two screws 60 also performing fixing the plate 59. The external air sucked by the ventilator 58 through the orifices made in the plate 59 is ejected through the lateral orifices 61, which allows the transversal partition 57 and the external blades 62 to be cooled down. It is to be noted that the blades 62 are of low dimensions of about the thickness of the core 54 and in limited number (nine in FIG. 2).

A board 1 supporting a light-emitting diode is fixed onto the distal face of the partition 57. The proximal face of the board 1 is for example in a thermally conductive metal such as aluminum. The board 1 is for example glued onto the distal face of the partition 57 using an adhesive film in thermal silicon. The board 1 may also be fixed attached to the partition 57 using three screws 63 introduced into orifices 4 made in the board 1 and screwed in three internally threaded orifices 64 made to that end in the partition 57.

The cylindrical external part of the distal axial orifice 56 made in the core 54 is encircled by the cylindrical freely rotating ring 53 which proximal part has an internal flange 65 and the distal part an internal threading 66. The ring 53 is maintained in position by a circular plate 67 which proximal face 68 is introduced into the distal end of the axial distal orifice 56 of the core 54 and which central part 69 comes in support on the distal face 70 of the core. The central part 69 has a diameter greater than that of the internal flange 65 of the ring 53 in order to form with the core an annular groove 71 wherein the flange 65 of the ring 53 is maintained.

The plate 66 comprises in addition an axial cylindrical tube 72 attached to the distal face of the plate 67 and intended for housing the lighting endpiece 13. The distal face of the circular plate 67 which thus has an annular shape is used as a support for the proximal face electrically insulated from an annular printed circuit board 73 which distal face supports in particular a current regulator powering the light-emitting diode. The distal part of the light generator 50 comprises a cylindrical tubular part 74 having a distal transversal partition 75 wherein an axial circular orifice 76 is made allowing the axial cylindrical tube 72 which proximal tubular part has an external diameter substantially identical to the internal diameter of the central part of the circular orifice 76 to pass. The proximal part of the circular orifice 76 has an internal diameter lower than the external diameter of the tube 72 so as to form a shoulder against which the tube 72 comes to a stop.

The male electric connection base 51 is fixed in an off-centered orifice 78 formed in the part 74, through a tubular part 77 made in an electrically insulating material. To that end, the proximal part of the tubular part 77 has an external threading provided for being screwed in the off-centered orifice 78 which is internally threaded. The distal part of the tubular part 77 also has an internal threading wherein the male electric connection base 51 is screwed.

The mechanical assembly of the various elements of the light generator 50 is performed using two screws 79 successively crossing the part 74 through two orifices 80, two cylindrical tubular through bolts 81, the printed circuit board 73 through two orifices 82, the circular plate 67 through two orifices 83 and crossing through two out of six lateral notches 5 of the board 1 supporting the light-emitting diode. The two screws 79 are eventually screwed in two internally threaded orifices 84 provided to that end in the medial transversal partition 57 of the core 54.

A supply cable 85 of the ventilator 58 successively passes through an orifice 86 made in the medial transversal partition 57 of the core 54, through one of the six lateral notches 5 of the board 1, in an orifice 87 made in the circular plate 67 and an orifice 88 formed in the printed circuit board 73. The distal end of the cable 85 is soldered onto the distal face of the printed circuit board 73.

A supply cable 89 of the light-emitting diode has a proximal end which is soldered onto two conductive connection pads 6 embedded on the distal face of the board 1 supporting the diode. The cable 89 successively crosses the orifice 87 made in the circular plate 67 and the orifice 88 made in the printed circuit 73. The distal end of the cable 89 is soldered onto the distal face of the printed circuit board 73.

A supply cable 91 of the light generator 50 directly links the distal face of the printed circuit board 73 to the male connection base 51 crossing through the insulating part 77 fixed in the part 74.

The precise positioning of the bundle of lighting fibers, firmly maintained in the lighting endpiece 13, against the emitting surface 2a of the diode 2 is successively performed by the connection part 30 wherein the endpiece 13 is maintained without clearance, and by the cylindrical tube 72 of the circular part 67, maintained without clearance by the cylindrical tubular part 74 and wherein the proximal end of the endpiece 13 is inserted without clearance, the proximal part 68 of the actual circular part 67 being maintained without clearance in the axial orifice 56 of the core 54.

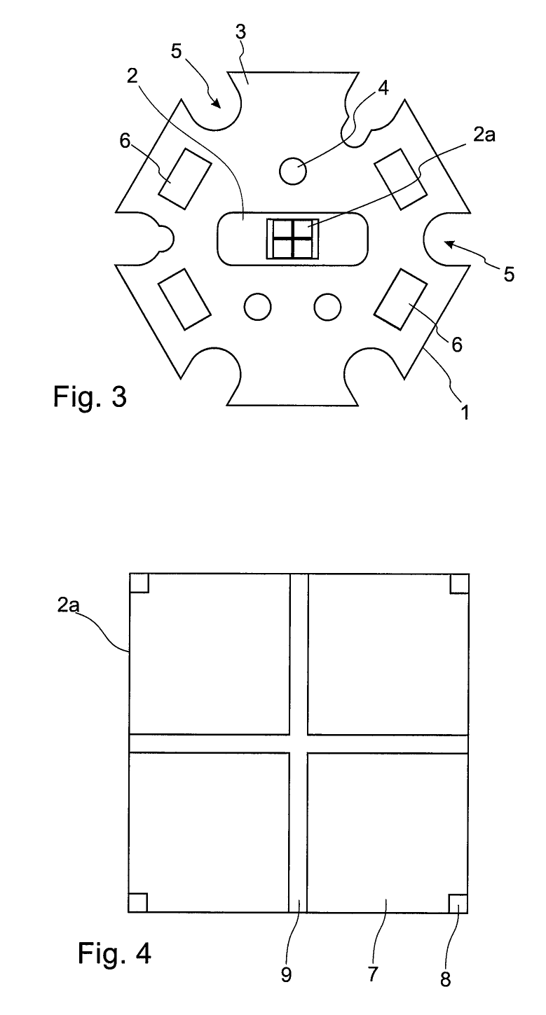

FIG. 3 shows in greater details the board 1 supporting the light-emitting diode 2.

The board 1 has for example a substantially hexagonal shape inscribed in a circle for example of around 21.6 mm of diameter. The diode is fixed to the board so that the light-emitting surface 2a thereof is centered on the board.

The board 1 comprises in addition fixing holes 4, for example three, lateral notches 5 formed in the angles of the hexagon, for example six notches, and connection pads 6 distributed on the board, for example four connection pads, allowing the two wires powering the diode to be connected. The board 1 for example comprises a layer formed by a printed circuit board 3 which rear face (not shown in the figure) is covered by a layer in a good thermally conductive material, for example aluminum. The board 1 is fixed on the partition 57 of the core 54, the thermally conductive face of the board being in contact with the partition, so as to be thermally linked to the radiator formed by the blades 62. The thermally conductive face of the board may in addition be covered by an interposed layer in thermal silicon provided for facilitating the evacuation of the heat given off by the diode and collected by the thermally conductive layer of the board 1 toward the radiator.

FIG. 4 shows an example of shape of emitting surface 2a of the light-emitting diode 2. In FIG. 4, the emitting surface 2a has a shape globally substantially square formed by the juxtaposition of four emitting areas 7 of substantially square shape, spaced out from one another by straight strips 9.

By way of example, each emitting area 7 has a square shape of 0.95 mm side, the respective centers of the emitting areas being separated from one another by a distance equal to 1.1 mm. A square part 8 of 0.15 mm side has been removed from each of the four emitting areas in an angle exterior to the emitting surface 2a. The straight strips 9 have a width of around 0.15 mm.

The light-emitting diode 2 may thus have the features specified in the following table:

TABLE 1

| | |
|---|---|
| Manufacturer | OSRAM |
| Model | LEWE2A |
| Color temperature | 5600° K |
| Illumination angle | 120° (for 50% of the luminous flux) |
| Emitting surface | 4.4 mm² (2.1 × 2.1 mm) |
| Electric power | 18 W |
| Light efficacy | 27 Lm/W (for 700 mA) |
| Luminance | 16.106 cd/m² (for 700 mA) |

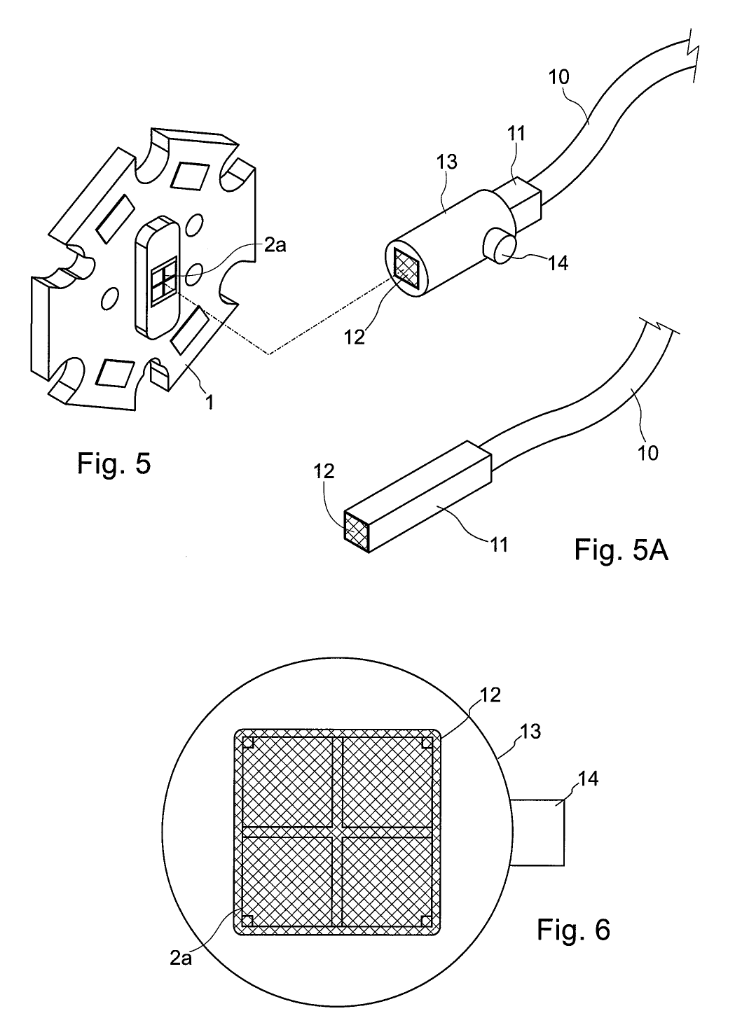

FIGS. 5 and 5A show a first embodiment of a coupling device allowing the light-emitting diode 2 to be associated to a bundle of lighting fibers 10. This embodiment is particularly adapted to the coupling of a bundle of lighting fibers having a section of around 5 mm², which is usually found in a videoendoscopic probe of 8 mm of diameter.

FIG. 5A shows the proximal part of the bundle of lighting fibers 10, introduced and then fixed, for example using adapted glue, in a sleeve 11. The internal section of the sleeve 11 has a substantially square shape. After carefully polishing the proximal face 12 of the bundle of lighting fibers 10, the sleeve 11 is introduced and then fixed, for example using glue, in an axial housing of square section made to that end in the lighting endpiece 13. The angular position of the lateral pin 14 on the endpiece 13 is determined so that the whole emitting surface 2a of the light-emitting diode 2 is covered by the proximal face 12 of the bundle of lighting fibers.

FIG. 6 shows the proximal face of the lighting endpiece 13 superimposed to the light-emitting surface 2a of the diode 2. The proximal face 12 of the bundle of lighting fibers is shown in the figure by a doubly hatched area. The proximal face 12 of the bundle of lighting fibers appears in the figure slightly bigger than the emitting surface 2a. The internal section of the sleeve 11 may thus have for example a side of around 2.3 mm. As shown in FIG. 6, the angular position of the pin 14 on the endpiece 13 is provided to ensure that the emitting surface 2a of substantially square shape is inscribed in the square shape of the proximal face 12 of the bundle of lighting fibers 10.

During its assembly in the light generator 50, the endpiece 13 is positioned longitudinally so that the proximal face 12 of the lighting bundle comes substantially in contact with the emitting surface 2a. The longitudinal position of the pin 14 on the endpiece 13 is determined so as to substantially obtain this contact.

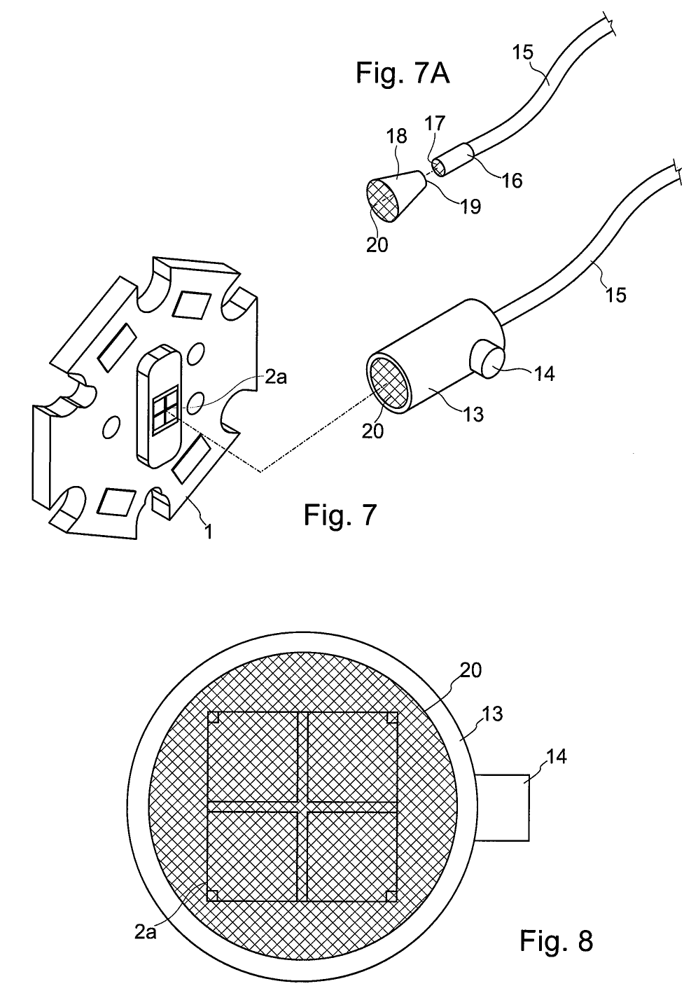

FIGS. 7 and 7A show a second embodiment of a coupling device allowing the light-emitting diode 2 to be associated to a bundle of lighting fibers 15. This embodiment is particularly adapted to the coupling of a bundle of lighting fibers having a section of around 2 mm², which is usually found in a videoendoscopic probe of 6 mm of diameter.

FIG. 7A shows the end of the bundle of lighting fibers and an optical component for transmitting light 18 of substantially tapered shape with a distal face 19 corresponding to the small base of the tapered shape, and a proximal face corresponding to the big base of the tapered shape. The distal face 19 is coupled to the proximal face 17 of the bundle of lighting fibers 15. To that end, the distal face 19 has a surface substantially identical to that of the proximal face 17. The proximal face 20 of the optical component 18 has a circular shape adapted to cover the whole emitting surface 2a of the diode 2. Thus, the proximal face 20 may for example have a diameter of around 3 mm, while the distal face 19 has a diameter of around 1.6 mm corresponding to the diameter of the bundle of fibers 15.

The proximal part of the bundle of lighting fibers 15 is introduced, and then fixed for example by gluing, in a cylindrical sleeve 16. The proximal face 17 of the bundle of lighting fibers is then carefully polished so that it coincides with the proximal face of the sleeve 16. The optical component 18 is then introduced, and then fixed for example by gluing, in a conical housing made to that end in the proximal part of the endpiece 13, so that the proximal face 20 of the optical component substantially coincides with the proximal face of the endpiece 13. The sleeve 16 is then introduced and then fixed, for example by gluing in an axial cylindrical housing made to that end in the distal part of the endpiece 13, so that the proximal face 17 of the bundle of fibers comes in close contact with the distal face 19 of the optical component with which it is fixed for example by means of a transparent glue.

The optical component 18 may be formed in an optical material, such as for example quartz, which lateral face has been subjected to a reflective process. The optical component 18 may also be formed by several conical lighting fibers.

During the assembly of the lighting endpiece 13 in the light generator 50, the endpiece 13 is positioned longitudinally thanks to the pin 14, so that the proximal face 20 of the optical component 18 comes in close contact with the emitting surface 2a of the light-emitting diode 2 and covers the whole surface 2a.

FIG. 8 shows the proximal face of the lighting endpiece 13 superimposed to the light-emitting surface 2a of the diode 2. The proximal face 20 of the optical component 18 is shown in the figure by a doubly hatched area. Thus, in FIG. 8, the proximal face 20 totally covers the emitting surface 2a.

Similar arrangements may be adopted to couple the light-emitting diode 2 to a cylindrical bundle of lighting fibers having a section which surface is lower than the emitting surface 2a. Thus, it is possible to couple the diode 2 to a bundle of lighting fibers having a surface of 1 mm², which is usually found in videoendoscopic probes of 4 mm diameter. Indeed, the implementation of an optical component of tapered shape which proximal face has a diameter of around 3 mm and distal face a diameter of around 1.2 mm is enough.

It is to be noted that the light transmission optical component 18 described hereinbefore allows the light-emitting diode to be associated to a bundle of lighting fibers which section has a surface lower than that of the emitting surface of the diode. This device therefore operates conversely to prior art devices wherein such a component was associated to older diode models, having an emitting surface lower than that of the section of the bundle of optical fibers to be connected.

It is also to be noted that since the proximal face 20 of the optical component 18 is circular and centered on the emitting surface 2a of the diode, it is not required to maintain the lighting endpiece 13 in an angular position determined in relation to the diode.

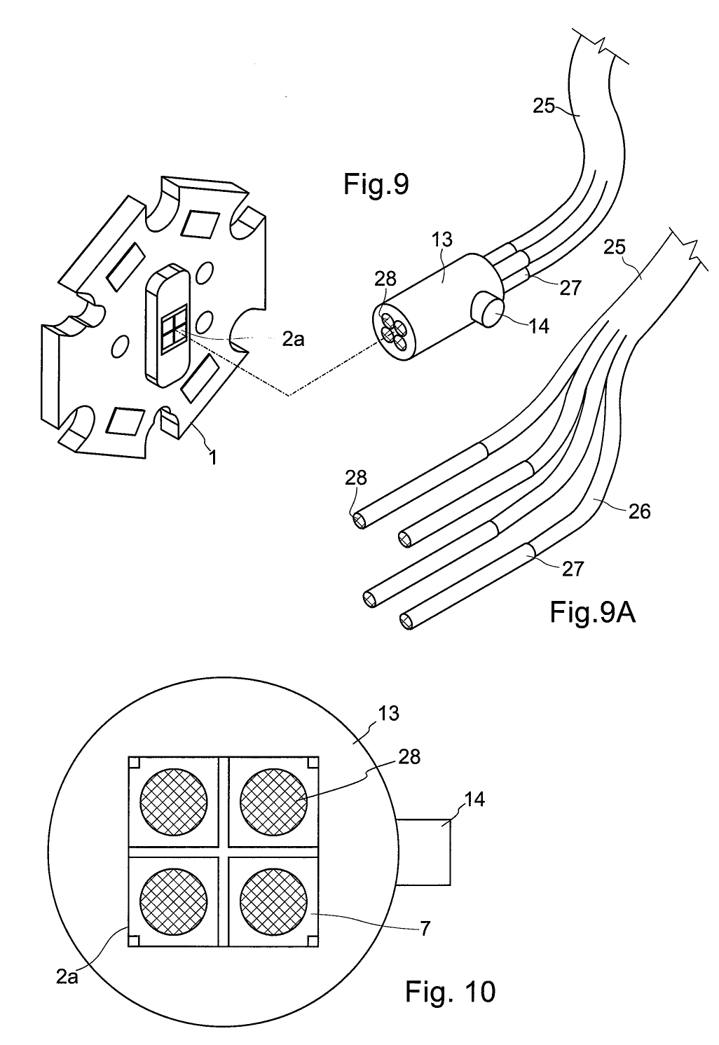

FIGS. 9 and 9A show a third embodiment of a coupling device allowing the light-emitting diode 2 to be associated to a bundle of lighting fibers. This embodiment is also particularly adapted to a bundle of lighting fibers 25 of a videoendoscopic probe of 6 mm of diameter, which section has a surface of around 2 mm².

FIG. 9A shows the proximal part of the bundle of lighting fibers 25, divided into four sub-bundles 26. Each sub-bundle has for example a section having a surface of 0.5 mm². The proximal part of each sub-bundle 26 is introduced, and then fixed, for example using glue, into a cylindrical tubular sleeve 27 having an internal diameter of around 0.8 mm. The proximal faces 28 of the four sub-bundles 26 are then carefully polished. The four sleeves 27 are then introduced, and then fixed for example by gluing, into four longitudinal cylindrical housings made to that end in the lighting endpiece 13. As described hereinbefore, the endpiece 13 is provided with a lateral pin 14 allowing the angular positioning of the proximal face of the endpiece to be adjusted on the emitting surface 2a of the light-emitting diode 2, so that the axes of the four cylindrical housings made in the endpiece 13 substantially pass through the centers of the four emitting areas 7 forming the emitting surface 2a.

During the assembly of the lighting endpiece 13 in the light generator 50, the endpiece 13 is positioned longitudinally so that the proximal face 28 of each sub-bundle 26 comes in contact with the emitting surface 2a of the light-emitting diode 2, and that the proximal faces 28 of the four sub-bundles 26 of lighting fibers are respectively centered on the four emitting areas 7 constituting the emitting surface 2a.

FIG. 10 shows the emitting surface 2a of the diode 2, superimposed with the proximal face of the lighting endpiece 13. The doubly hatched areas shown in the figure correspond to the respective proximal surfaces 28 of the four sub-bundles 26. FIG. 10 shows that in coupled position, the proximal faces 28 of the sub-bundles 26 are centered on the emitting areas 7 of the diode, without completely covering them.

Similar arrangements may be adopted to couple the light-emitting diode 2 to a bundle of lighting fibers having a section which surface is lower than the emitting surface 2a of the diode 2. Thus, in the case of a bundle of fibers having a section of 1 mm² corresponding to a videoendoscopic probe of 4 mm of diameter, the bundle of lighting fibers may be divided into four cylindrical sub-bundles housed in cylindrical tubular sleeves, each having an internal diameter of around 0.6 mm.

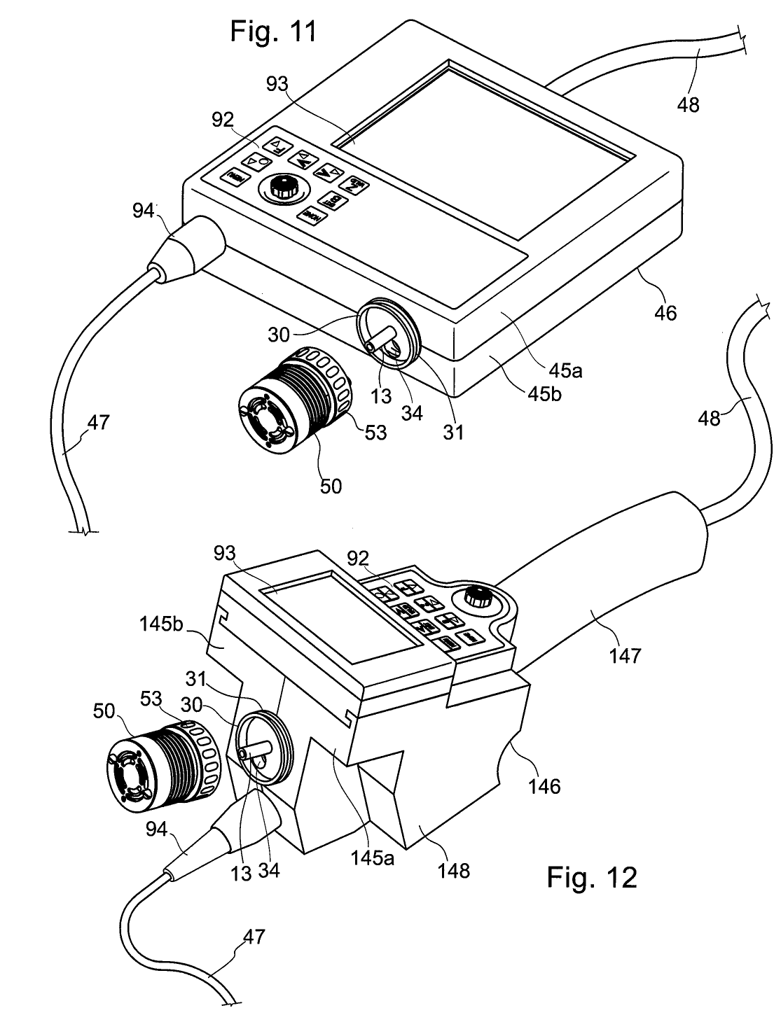

FIGS. 11 and 12 show by way of example, the arrangement of the composite connection part 30 on the front face of a handle of videoendoscopic probe. In FIGS. 11 and 12, the handle 46,146 comprises two half-shells 45a, 45b, 145a, 145b which may be made in injected plastic. The connection part 30 which allows the removable light generator 50 to be associated to the handle, is fixed onto a front face of the handle between the two half-shells as shown in FIG. 2. The front face is also attached to a sleeve 94 housing the proximal end of an inspection tube 47. A rear face of the handle supports a connection base (not shown) of a removable umbilical tube 48. Thus, the bundle of lighting fibers housed in the inspection tube gets into the control handle and gets out thereof through the endpiece 32 housed in the connection part 30.

In FIG. 11, the handle 46 has a substantially parallelepiped shape comprising a higher half-shell 45a and a lower half-shell 45b, the higher half-shell 45a housing a visualization screen 93 and a control keyboard 92.

In FIG. 12, the control handle 146 comprises for example a left half-shell 145a and a right half-shell 145b. The half-shells 145a, 145b, once assembled one to the other, have a rear part 147 forming a handle intended for being maintained with a hand, and a front part 149 integrating the visualization screen 93 and the control keyboard 92.

FIGS. 11 and 12 show that the lighting device may be mounted on handles of different shapes.

It will be clear to those skilled in the art that the present invention is susceptible of various other embodiments and applications. In particular, the invention is not limited to a case 54 of a thermally conductive light generator. Indeed, it may be provided that the case is not conductive and comprises an external radiator thermally linked to the diode. Globally, the need to cool down the diode depends on the features and in particular the efficacy of the diode and therefore on the technology implemented.

The present invention is not limited either to a source of light comprising one light-emitting diode only. The present invention makes it possible indeed to provide several diodes and a lighting endpiece wherein the bundle of lighting fibers is divided into several sub-bundles, as considered in FIGS. 9 and 9A, and wherein the proximal ends of the sub-bundles are arranged according to the distribution of the emitting surfaces of the diodes in the case.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A lighting device for videoendoscopic probe equipped with a bundle of lighting fibers, the lighting device comprising:
a light generator that includes a case and a light-emitting diode mounted in the case;
a lighting endpiece configured to be attached to a proximal end of the bundle of lighting fibers, and configured to adapt a surface of the proximal end of the bundle of lighting fibers to a light-emitting surface of the diode; and
a connection part configured to be fixed to a handle of the videoendoscopic probe, and to couple with the case, the case and the connection part being configured to maintain the lighting endpiece on the light emitting surface.

2. The lighting device according to claim 1, wherein the case is thermally linked to the diode and is configured to evacuate heat given off by the diode.

3. The lighting device according to claim 1, comprising a forced cooling device installed in the case and thermally linked to the diode.

4. The lighting device according to claim 1, wherein the case comprises blades forming a radiator thermally linked to the diode.

5. The lighting device according to claim 1, wherein the case is configured so as to be removably fixed to the connection part.

6. The lighting device according to claim 5, comprising a ring encircling the case and fixed to the case so as to be able to freely turn around its axis, the connection part comprising an external thread configured to cooperate with an internal thread provided in the ring and thus performing fixing the case to the connection part.

7. The lighting device according to claim 1, wherein the light-emitting surface of the light-emitting diode is greater than 3 mm², and the light-emitting diode consumes an electric power greater than 10 Watts.

8. The lighting device according to claim 1, wherein the light-emitting surface of the light-emitting diode is around 4 mm², and the light-emitting diode consumes an electric power greater than 15 Watts.

9. The lighting device according to claim 1, wherein the lighting endpiece is configured to couple the bundle of lighting fibers, having a proximal surface of around 5 mm², to the light-emitting surface of around 4 mm².

10. The lighting device according to claim 9, wherein the light-emitting surface of the diode is of substantially square shape, the proximal face of the bundle of lighting fibers being conformed into the lighting endpiece so as to have a substantially square shape.

11. The lighting device according to claim 10, wherein the lighting endpiece comprises a lateral lug cooperating with a housing provided in the connection part to maintain the proximal end of the bundle of lighting fibers substantially in contact with the emitting surface and in an angular configuration able to cover the whole light-emitting surface.

12. The lighting device according to claim 1, wherein the lighting endpiece is configured to couple a bundle of lighting fibers having a proximal surface of around 2 mm² to the light-emitting surface of around 4 mm².

13. The lighting device according to claim 1, wherein the lighting endpiece is configured to couple the bundle of lighting fibers having a proximal surface of around 1 mm² to the emitting surface of around 4 mm².

14. The lighting device according to claim 12, wherein the lighting endpiece comprises an optical component having a proximal face configured to cover the light-emitting surface, and a distal face substantially identical to the proximal end of the bundle of lighting fibers, the proximal face having a surface greater than that of the distal face.

15. The lighting device according to claim 12, wherein the bundle of lighting fibers includes sub-bundles having proximal ends and the lighting endpiece comprises longitudinal cylindrical housings configured to receive the proximal ends of the sub-bundles, the cylindrical housings being arranged to center the proximal ends of the sub-bundles on light-emitting areas of the light-emitting diode.

16. The lighting device according to claim 15, wherein the lighting endpiece comprises a lateral lug cooperating with a housing provided in the connection part to maintain each proximal end of the sub-bundles centered on a respective light-emitting area and substantially in contact therewith.

17. The lighting device according to claim 1, wherein the connection part comprises an electrical connection base configured to couple with an electrical connection base attached to the case when the case and the connection part are coupled.

18. The lighting device according to claim 17, wherein the lighting endpiece is axially maintained in the connection part and the case, the electrical connection bases being fixed off-center in the connection part and the case, thus defining an angular configuration of fixation of the case on the connection part.

19. A videoendoscopic probe comprising:
a bundle of lighting fibers;
a control handle comprising a case; and
a lighting device including:
a light generator having a case and a light-emitting diode mounted in the case of the light generator,
a lighting endpiece attached to a proximal end of the bundle of lighting fibers, and configured to adapt a surface of the proximal end of the bundle of lighting fibers to a light-emitting surface of the diode, and
a connection part configured to be fixed to the control handle, and to couple with the case of the light generator, the case of the light generator and the connection part being configured to maintain the lighting endpiece on the light emitting surface.

20. The probe according to claim 19, wherein the case of the light generator is thermally linked to the diode and is configured to evacuate heat given off by the diode.

21. The probe according to claim 19, comprising a forced cooling device installed in the case of the light generator and thermally linked to the diode.

22. The probe according to claim 19, wherein the case of the light generator comprises blades forming a radiator thermally linked to the diode.

23. The probe according to claim 19, wherein the case of the light generator is configured so as to be removably fixed to the connection part.

24. The lighting device according to claim 23, comprising a ring encircling the case of the light generator and fixed to the case of the light generator so as to be able to freely turn around its axis, the connection part comprising an external thread configured to cooperate with an internal thread provided in the ring and thus performing fixing the case of the light generator to the connection part.

25. The probe according to claim 19, wherein the light-emitting surface of the light-emitting diode is greater than 3 mm², and the light-emitting diode consumes an electric power greater than 10 Watts.

26. The probe according to claim 19, wherein the light-emitting surface of the light-emitting diode is around 4 mm², and the light-emitting diode consumes an electric power greater than 15 Watts.

27. The probe according to claim 19, wherein the lighting endpiece is configured to couple the bundle of lighting fibers having a proximal surface of around 5 mm², to the light-emitting surface of around 4 mm².

28. The probe according to claim 27, wherein the emitting surface of the diode is of substantially square shape, the proximal face of the bundle of lighting fibers being conformed into the lighting endpiece so as to have a substantially square shape.

29. The probe according to claim 28, wherein the lighting endpiece comprises a lateral lug cooperating with a housing provided in the connection part to maintain the proximal end of the bundle of lighting fibers substantially in contact with the emitting surface and in an angular configuration able to cover the whole light-emitting surface.

30. The probe according to claim 19, wherein the lighting endpiece is configured to couple the bundle of lighting fibers having a proximal surface of around 2 mm² to the light-emitting surface of around 4 mm².

31. The probe according to claim 19, wherein the lighting endpiece is configured to couple the bundle of lighting fibers, having a proximal surface of around 1 mm², to the emitting surface of around 4 mm².

32. The probe according to claim 30, wherein the lighting endpiece comprises an optical component having a proximal face configured to cover the light-emitting surface, and a distal face substantially identical to the proximal end of the bundle of lighting fibers, the proximal face having a surface greater than that of the distal face.

33. The probe according to claim 30, wherein the bundle of lighting fibers includes sub-bundles having proximal ends and the lighting endpiece comprises longitudinal cylindrical housings configured to receive the proximal ends of sub-bundles, the cylindrical housings being arranged to center the proximal ends of the sub-bundles on light-emitting areas of the light-emitting diode.

34. The probe according to claim 33, wherein the lighting endpiece comprises a lateral lug cooperating with a housing provided in the connection part to maintain each proximal end of the sub-bundles centered on a respective light-emitting area and substantially in contact therewith.

35. The probe according to claim 19, wherein the connection part comprises an electrical connection base configured to couple with an electrical connection base attached to the case of the light generator when the case of the light generator and the connection part are coupled.

36. The probe according to claim 35, wherein the lighting endpiece is axially maintained in the connection part and the case of the light generator, the electrical connection bases being fixed off-center in the connection part and the case of the light generator, thus defining an angular configuration of fixation of the case of the light generator on the connection part.

37. The probe according to claim 19, wherein the connection part comprises an annular groove provided to receive the edges of an annular orifice made by two half-shells forming at least partially the case of the control handle.

38. The probe according to claim 37, wherein the half-shells are made of a plastic compound.
